(19) United States
(12) Patent Application Publication
(10) Pub. No.: US 2023/0232538 A1
(43) Pub. Date: Jul. 20, 2023

(54) SUBSTRATE FOR PRINTED WIRING BOARD AND MULTILAYER SUBSTRATE

(71) Applicants: SUMITOMO ELECTRIC INDUSTRIES, LTD., Osaka-shi, Osaka (JP); SUMITOMO ELECTRIC PRINTED CIRCUITS, INC., Koka-shi, Shiga (JP)

(72) Inventors: Toshiki IWASAKI, Osaka-shi (JP); Makoto NAKABAYASHI, Osaka-shi (JP); Satoshi KIYA, Koka-shi (JP)

(73) Assignees: SUMITOMO ELECTRIC INDUSTRIES, LTD., Osaka-shi, Osaka (JP); SUMITOMO ELECTRIC PRINTED CIRCUITS, INC., Koka-shi, Shiga (JP)

(21) Appl. No.: 18/010,050

(22) PCT Filed: Jun. 25, 2021
(86) PCT No.: PCT/JP2021/024173

§ 371 Date: Dec. 13, 2022

(30) Foreign Application Priority Data
Jun. 30, 2020 (JP) 2020-113450

(51) Int. Cl. H05K 3/02; H05K 1/03

(52) U.S. Cl. CPC H05K 3/022; H05K 1/0366; H05K 1/036; H05K 2201/015

(57) ABSTRACT

A substrate for a printed wiring board includes a base layer, and a copper foil directly or indirectly stacked on at least a part of one or both surfaces of the base layer. The base layer includes a matrix containing a fluororesin as a main component and one or more reinforcing material layers included in the matrix, and a ratio B/A is 0.003 to 0.37, where A is an average thickness of the base layer, and B is an average distance between a surface of the copper foil facing the matrix and a surface of a reinforcing material layer closest to the surface of the copper foil facing the copper foil.

### TECHNICAL FIELD

The present disclosure relates to a substrate for printed wiring board and a multilayer substrate. This application claims priority based on Japanese Patent Application No. 2020-113450 filed on Jun. 30, 2020, and the entire contents of the Japanese patent application are incorporated herein by reference.

### BACKGROUND ART

Conventionally, a printed wiring board having a fluororesin substrate has been known. Since a fluororesin has a lower dielectric constant than an epoxy resin, a printed wiring board having a fluororesin substrate is used as a circuit board for high-frequency signal processing. In such a printed wiring board, it has been proposed to dispose a base layer composed of a glass cloth impregnated with a fluororesin on at least one side of a fluororesin sheet (see JP2002-158417A). Since the insulating layer is formed by the fluororesin sheet and the base layer, the printed wiring board has a higher mechanical strength than a printed wiring board using a polytetrafluoroethylene (PTFE) sheet alone, and warpage and distortion of the substrate are suppressed.

### PRIOR ART DOCUMENT

### Patent Literature

[Patent Document 1] JP2002-158415A

### SUMMARY OF THE INVENTION

A substrate for a printed wiring board according to an aspect of the present disclosure, includes a base layer, and a copper foil directly or indirectly stacked on at least a part of one or both surfaces of the base layer. The base layer includes a matrix containing a fluororesin as a main component and one or more reinforcing material layers included in the matrix, and a ratio B/A is 0.003 to 0.37, where A is an average thickness of the base layer, and B is an average distance between a surface of the copper foil facing the matrix and a surface of a reinforcing material layer closest to the surface of the copper foil facing the copper foil.

### BRIEF DESCRIPTION OF DRAWINGS

FIG. 1 is a schematic cross-sectional view showing a substrate for printed wiring board according to an embodiment of the present disclosure.

FIG. 2 is a schematic cross-sectional view showing a multilayer substrate according to an embodiment of the present disclosure.

FIG. 3 is a schematic cross-sectional view showing a multilayer substrate according to another embodiment of the present disclosure.

### DETAILED DESCRIPTION OF THE PREFERRED EMBODIMENTS

### Problems to be Solved by the Present Disclosure

In general, a substrate for printed wiring board may be used in a bent state or may be bent when incorporated into a device such as a mobile phone in a manufacturing process. However, a substrate for printed wiring board using a fluororesin substrate including a reinforcing material such as glass cloth may be broken when repeatedly bent.

The present disclosure has been made in view of the above circumstances, and an object thereof is to provide a substrate for printed wiring board having excellent bending strength.

### Effects of the Present Disclosure

The substrate for printed wiring board of the present disclosure has excellent bending strength.

### Description of Embodiments of the Present Disclosure

First, embodiments of the present disclosure will be listed and described.

(1) A substrate for a printed wiring board according to an aspect of the present disclosure, includes a base layer, and a copper foil directly or indirectly stacked on at least a part of one or both surfaces of the base layer. The base layer includes a matrix containing a fluororesin as a main component and one or more reinforcing material layers included in the matrix, and a ratio B/A is 0.003 to 0.37, where A is an average thickness of the base layer, and B is an average distance between a surface of the copper foil facing the matrix and a surface of a reinforcing material layer closest to the surface of the copper foil facing the copper foil.

The substrate for printed wiring board used as the multilayer substrate preferably has a bending strength capable of withstanding 60 times or more of bending. However, when the substrate for printed wiring board is bent into a U-shape, peak portions and valley portions are generated, and components (for example, fluororesin) of the substrate for printed wiring board are in a state of being pulled at the peak portions and compressed at the valley portions. Generally, a substrate for printed wiring board is provided with copper foil on its surface, and when the substrate for printed wiring board is bent into a U-shape, the copper foil cannot withstand the stress generated by the bending, so that the copper foil is broken. The present inventors have found that the breakage of the copper foil is likely to occur from both ends of the substrate in a direction perpendicular to the bending direction of the substrate for printed wiring board. Therefore, the present inventors assumed that “when the substrate for printed wiring board is bent, since the fluororesin is soft, so fluororesin is compressed at the valley portions, which causes a large strain in the fluororesin. The copper foil adhered to the fluororesin cannot follow the strain of the fluororesin, and thus is broken.” Based on this assumption, the present inventors have found that the bending strength of the substrate for printed wiring board can be improved by reducing the strain of the fluororesin, that is, the force of the fluororesin to protrude, and the breakage of the substrate for printed wiring board due to bending can be suppressed. In the substrate for printed wiring board according to an aspect of the present disclosure, since the ratio B/A is 0.003 to 0.37, the outermost matrix (main component is fluororesin), that is, the matrix (fluororesin layer) between the copper foil and the reinforcing material layer closest to the copper foil is reduced as much as possible. Therefore, when the substrate for printed wiring board is bent, the force (strain of the matrix) of the matrix (fluororesin layer) trying to protrude is reduced, and the load on the copper foil is suppressed. Therefore, the substrate for printed wiring board according to an aspect of the present disclosure has excellent bending strength.

(2) The ratio B/A may be 0.10 to 0.25. When the ratio B/A is 0.10 to 0.25, the bending strength is more excellent.

The “main component” is a component having the highest content. The “main component” is, for example, a component having a content of 50 mass % or more, and may be a component having a content of 90 mass % or more. The “average thicknesses” of the base layer or the reinforcing material layer refers to the distance between the average line of the interface on the front surface and the average line of the interface on the back surface in the visual field to be observed of the base layer or the reinforcing material layer in the cross-section obtained by cutting a substrate for printed wiring board or a multilayer substrate in a thickness direction. The cross-section is observed with a scanning electron microscope or an optical microscope. The size of the visual field to be observed is 0.1 μm×0.1 μm to 3 mm×3 mm. The “average line” refers to a virtual straight line drawn along an interface such that the total area of peaks (total area above the virtual straight line) and the total area of valleys (total area below the virtual straight line) defined between the interface and the virtual straight line are equal to each other. The “average distance B” is an average value of five measured values when a distance b between a surface of the copper foil facing the matrix and a surface of a reinforcing material layer closest to the surface of the copper foil facing the copper foil is measured at arbitrary five points. The average distance B corresponds to an average value of five measured values when the distance between the outermost surface of the reinforcing material layer disposed on both end sides in the thickness direction of the base layer and the surface of the copper foil on the side facing the outermost surface of the reinforcing material layer is measured at five points. The distance b is measured by observing a cross-section obtained by cutting the substrate for printed wiring board or multilayer substrate in the thickness direction. The cross-section is observed with a scanning electron microscope or an optical microscope. The size of the visual field to be observed is 0.1 μm-0.1 μm to 3 mm×3 mm. Further, when copper foils are disposed on both sides of the base layer, B can be obtained for each copper foil and the reinforcing material layer closest to each copper foil. In the substrate for printed wiring board according to one aspect of the present disclosure, the ratio B/A is 0.003 to 0.37 for any B.

(3) The fluororesin may be any one of a tetrafluoroethylene-hexafluoropropylene copolymer (FEP), a tetrafluoroethylene-perfluoroalkyl vinyl ether copolymer (PFE), and polytetrafluoroethylene (PTFE) or a combination thereof. When the fluororesin is any one of FEP, PFE, and PTFE or a combination thereof, the effect of suppressing the transmission loss can be further enhanced.

(4) A ratio of a sum of average thicknesses of the one or more reinforcing material layers to the average thickness of the base layer may be 0.01 to 0.99.

(5) A ratio of a sum of average thicknesses of the one or more reinforcing material layers to the average thickness of the base layer may be 0.20 to 0.50.

(6) A ratio of a sum of average thicknesses of the one or more reinforcing material layers to the average thickness of the base layer may be 0.22 to 0.47.

(7) A ratio of a sum of average thicknesses of the one or more reinforcing material layers to the average thickness of the base layer may be 0.25 to 0.45.

When the ratio of the sum of the respective average thicknesses of the reinforcing material layers to the average thickness of the base layer is 0.01 to 0.99, the bending strength and the transmission characteristics can be further improved. When the ratio of the sum of the respective average thicknesses of the reinforcing material layers to the average thickness of the base layer is 0.20 to 0.50, the bending strength and the transmission characteristics can be much further improved. When the ratio of the sum of the respective average thicknesses of the reinforcing material layers to the average thickness of the base layer is 0.22 to 0.47, the bending strength and the transmission characteristics can be much further improved. When the ratio of the sum of the respective average thicknesses of the reinforcing material layers to the average thickness of the base layer is 0.25 to 0.45, the bending strength and the transmission characteristics can be particularly improved. The “sum of the respective average thicknesses of the one or more reinforcing material layers” is the average thickness thereof when there is one reinforcing material layer, and is a value obtained by totaling the respective average thicknesses of the reinforcing material layers when there are a plurality of reinforcing material layers.

(8) The one or more reinforcing material layers each may include a glass cloth, a heat-resistant film, a resin cloth, or a nonwoven fabric. When the reinforcing material layer includes a glass cloth, a heat-resistant film, a resin cloth, or a nonwoven fabric, the bending strength of the substrate for printed wiring board may be further improved.

(9) The copper foil may be electrolytic copper foil or rolled copper foil. When the copper foil is electrolytic copper foil or rolled copper foil, better flexibility can be obtained while excellent transmission characteristics are obtained.

(10) The matrix may be divided into a plurality of layers. Since the matrix is divided into a plurality of layers, a substrate for printed wiring board having further excellent bending strength can be obtained.

(11) A multilayer substrate according to another aspect of the present disclosure, includes a plurality of the substrates for a printed wiring board according to one aspect of the present disclosure stacked on each other. In the multilayer substrate, since a plurality of substrates for printed wiring boards are stacked, it is possible to reduce strain due to compression of the outermost matrix (fluororesin layer) of the multilayer substrate and to suppress a load on the copper foil disposed on the outermost side. Therefore, the multilayer substrate according to another aspect of the present disclosure has excellent bending strength.

(12) The plurality of the substrates for a printed wiring board may be stacked on each other with a bonding sheet or an adhesive layer containing a silane coupling agent as a main component interposed therebetween. Since a plurality of substrates for printed wiring boards are stacked on each other with a bonding sheet or an adhesive layer containing a silane coupling agent as a main component interposed therebetween, good adhesiveness can be obtained between the plurality of substrates for printed wiring boards.

(13) The multilayer substrate according to another aspect of the present disclosure, may include a first substrate for a printed wiring board and a second substrate for a printed wiring board may be stacked on each other. The first substrate for a printed wiring board and the second substrate for a printed wiring board are each the substrate for a printed wiring board according to any one of (1) to (10). In the first substrate for a printed wiring board, the copper foil is directly or indirectly stacked on at least a part of each of both surfaces of the base layer, and in the second substrate for a printed wiring board, the copper foil is directly or indirectly stacked on at least a part of one surface of the base layer. Among the copper foils of the first substrate for a printed wiring board, the copper foil on which the second substrate for a printed wiring board is stacked is a first copper foil. The reinforcing material layer of the second substrate for a printed wiring board closest to the first copper foil is a first reinforcing material layer. A ratio D/A may be 0.003 to 0.37, where A is an average thickness of the base layer of the second substrate for a printed wiring board, and D is an average distance between a surface of the first copper foil facing the matrix of the second substrate for a printed wiring board and a surface of the first reinforcing material layer facing the first copper foil. With such a configuration, the load on the copper foil disposed inside the multilayer substrate can be suppressed. Therefore, the multilayer substrate has excellent bending strength. The “average distance D” is an average value of five measured values when a distance d between the surface of the first copper foil facing the matrix of the second substrate for printed wiring board and the surface of the first reinforcing material layer facing the first copper foil is measured at arbitrary five points. The method of measuring distance d is the same as the method of measuring distance b.

Details of Embodiments of the Present Disclosure

Hereinafter, a substrate for printed wiring board according to the present disclosure will be described with reference to the drawings.

<Substrate for Printed Wiring Board>

A substrate for printed wiring board according to the present disclosure includes a base layer and a copper foil directly or indirectly stacked on at least a part of one or both surfaces of the base layer. The base layer includes a matrix containing a fluororesin as a main component and one or more reinforcing material layers included in the matrix.

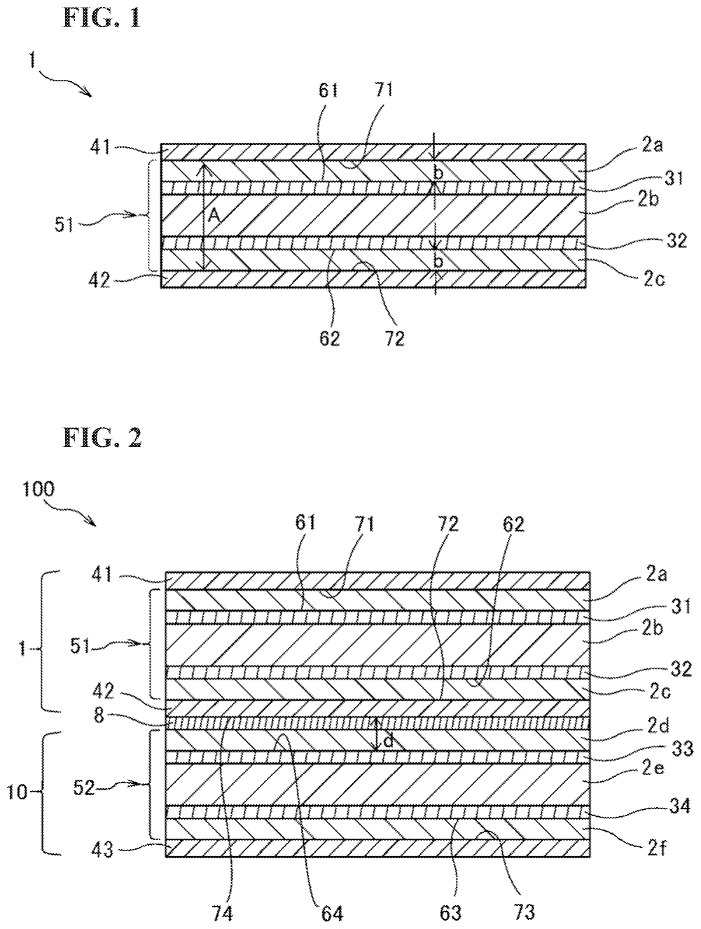

A substrate for printed wiring board 1 shown in FIG. 1 includes a base layer 51. Further, substrate for printed wiring board 1 includes copper foils 41 and 42 directly or indirectly stacked on both surfaces of a base layer 51. Base layer 51 containing fluororesin as the main component has the matrix composed of reinforcing material layers 31 and 32 and the fluororesin layer. In FIG. 1, the matrix is divided into three layers of a matrix 2a, 2b, and 2c by two reinforcing material layers 31 and 32. Matrix 2a is arranged to face copper foil 41, and the matrix 2c is arranged to face copper foil 42. Matrix 2b is arranged between reinforcing material layer 31 and reinforcing material layer 32.

[Base Layer]

The base layer includes the matrix and one or more reinforcing material layers included in the matrix. The matrix is a base material having fluororesin as the main component. The matrix is a portion other than the reinforcing material layer. In FIG. 1, the matrix has three layers (matrixes 2a, 2b, and 2c). The reinforcing material layer is arranged between the matrixes (matrix layers).

The fluororesin is a material having a relatively low relative dielectric constant, and the temperature dependence of the relative dielectric constant is small. Therefore, since the main component of the matrix is the fluororesin, the effect of suppressing the transmission loss is high in substrate for printed wiring board 1. The degree of crystallinity of the fluororesin is 50% to 60%. As described above, since the degree of crystallinity of the fluororesin is small, even if a specific change occurs in the crystal structure, it is presumed that a change in the electric characteristics or the like is small. Therefore, the fluororesin has good temperature dependence of electrical characteristics.

The fluororesin may be any one of tetrafluoroethylene-hexafluoropropylene copolymer (FEP), tetrafluoroethylene-perfluoroalkyl vinyl ether copolymer (PFE), and polytetrafluoroethylene (PTFE), or a combination thereof. When the fluororesin is any one of FEP, PFE, and PTFE or a combination thereof, the effect of suppressing the transmission loss can be further enhanced.

The matrix may contain components (optional components) other than the fluororesin. Examples of the optional component include a resin other than the fluororesin, a flame retardant, a flame retardant aid, a pigment, an antioxidant, a reflection-imparting agent, a masking agent, a lubricant, a processing stabilizer, a plasticizer, a foaming agent, a heat dissipating filler made of alumina, silicon nitride, or the like, and linear expansion reducing particles made of silica, titanium oxide or the like. The upper limit of the content of the optional component contained in the matrix may be 20 mass % or 10 mass %.

The base layer may have a hollow structure. When a hollow structure is provided, the relative dielectric constant can be small, the transmission loss can be suppressed more effectively.

The upper limit of the relative dielectric constant of the matrix may be 2.7 or 2.5. The lower limit of the relative dielectric constant may be 1.2 or 1.4. When the relative dielectric constant of the matrix exceeds 2.7, the dielectric loss tangent becomes too large, so that there is a possibility that the transmission loss cannot be sufficiently reduced and a sufficient transmission rate cannot be obtained. When the relative dielectric constant of the matrix is 2.5 or less, the transmission loss can be further reduced, and the transmission rate can be further increased. When the relative dielectric constant of the matrix is less than 1.2, there is a possibility that the circuit width cannot be made sufficiently small when the copper foil is etched in a pattern to provide a circuit on the substrate for printed wiring board, or there is a possibility that the strength of the substrate for printed wiring board is lowered. When the relative dielectric constant of the matrix is 1.4 or more, the circuit width can be made sufficiently small more easily, and the strength of the substrate for printed wiring board is less likely to decrease. The “relative dielectric constant” is measured using a cavity resonator. “ADMS01Oc” manufactured by AET, Inc., which is an apparatus for measuring a microwave-complex relative dielectric constant of an object to be measured, is used. First, a detector is attached to the cavity resonator corresponding to frequencies to be measured using torque wrenches, and a thickness of 0.821 mm, a width of 3.005 mm, and a frequency of 10 GHz are input as measurement conditions. After a blank measurement is performed in a state where the measurement sample is not contained, a reference sample made of polytetrafluoroethylene is set in the cavity resonator. The relative dielectric constant of the reference sample is measured and it is confirmed that the relative dielectric constant is 2.02 f 0.02. Next, the sample is punched out by using a dedicated sample cutter to prepare three rectangular measurement samples having a width of 3 mm and a length of 25 mm. The thickness of each measurement sample is measured on a surface plate using “Digimatic Indicator ID-H” manufactured by Mitutoyo Corporation. In addition, the width of each measurement sample is measured using “ABS digimatic caliper CD-AX” manufactured by Mitutoyo Corporation. As measurement conditions, the sum of the thicknesses of the three measurement samples, the average value of the widths of the three measurement samples, and a frequency of 10 GHz are input. Then, the three measurement samples in a stacked state are attached to a cavity resonator, and the relative dielectric constant is measured. The measurement is performed 10 times, and the average value of the 10 measurements is taken as the relative dielectric constant of the sample.

The upper limit of the linear expansion coefficient of the matrix may be 1.2×10⁻⁴/° C. The lower limit of the linear expansion coefficient may be 2×10⁻⁵/° C. When the linear expansion coefficient of the matrix exceeds 1.2×10⁻⁴/° C., there is a possibility that the volume of the base layer changes due to a temperature change, and the occurrence of warpage cannot be effectively suppressed. When the linear expansion coefficient of the matrix is less than 2-10⁻⁵/° C., there may be a problem in terms of cost. The “linear expansion coefficient” is measured as follows. First, the stretching ratios in the flow direction (MD direction) and the perpendicular direction (TD direction) are measured under the following conditions, and the stretching ratio/temperature is measured at intervals of 10° C., from 40 to 50° C., from 50 to 60° C., an so on, and this measurement is carried out up to 250° C. The average value of all measured values from 50° C. to 250° C. is taken as the linear expansion coefficient.

Apparatus name: SS7100 manufactured by Hitachi High-Tech Science Corporation
Sample length: 10 mm
Sample width: 4 mm
Initial load: 20.4 g/mm
Temperature at the start of heating: 30° C.
Temperature at the end of heating: 255° C.
Heating rate: 5° C./min
Atmosphere: nitrogen

(Reinforcing Material Layer)

The reinforcing material layer is a layer formed of the reinforcing material or a layer including a reinforcing material. When the substrate for printed wiring board has the reinforcing material layer, mechanical strength is improved. As the reinforcing material, for example, a film, a woven fabric (hereinafter also referred to as “cloth”), or a nonwoven fabric can be used.

The reinforcing material is not particularly limited as long as it has a linear expansion coefficient smaller than that of the matrix. The reinforcing material may have insulating properties, heat resistance so as not to melt and flow at the melting point of the fluororesin, tensile strength equal to or higher than that of the fluororesin, and corrosion resistance.

Examples of the reinforcing material include;

(a) a glass cloth obtained by processing glass fiber into a cloth shape;
(b) a fluororesin-containing glass cloth obtained by impregnating a glass cloth with the fluororesin, the glass cloth obtained by processing glass fiber into a cloth shape;
(c) an inorganic cloth obtained by processing inorganic fibers such as metal and ceramics into a cloth shape;
(d) a heat-resistant film including polyimide, aramid, polyether ether ketone, a liquid crystal polymer, polyamideimide, polybenzimidazole, polytetrafluoroethylene, tetrafluoroethylene-perfluoroalkyl vinyl ether copolymer, a thermosetting resin, a crosslinked resin, or the like as the main component;
(e) a resin cloth or the nonwoven fabric obtained by processing synthetic resin fibers such as polyimide, aramid, polyether ether ketone, liquid crystal polymer (LCP), polyether sulfone, polyamide imide, polysulfone, and polytetrafluoroethylene into a cloth shape.

The resin cloth and the heat-resistant film may have a melting point (or a heat distortion temperature) equal to or higher than a temperature of a thermal compression process in a method of manufacturing the base layer to be described below.

When the glass cloth, the inorganic cloth or the resin cloth is plain-woven, the base layer can be made thin. When the glass cloth, the inorganic cloth or the resin cloth is formed into a twill weave or a satin weave, the base layer can be made flexible. In addition, known weaving methods can be applied.

From the viewpoint of further improving the bending strength of the substrate for printed wiring board, the reinforcing material may be the glass cloth, the heat-resistant film, the resin cloth, or the nonwoven fabric. The main component of the heat-resistant film may be polyimide, aramid, polyetheretherketone, or a liquid crystal polymer.

When the reinforcing material is the fluororesin-containing glass cloth, the fluororesin impregnated into the glass cloth may be the same as the fluororesin of the main component of the matrix of the substrate for printed wiring board.

From the viewpoint of further improving the bending strength of the substrate for printed wiring board, the reinforcing material may be the glass cloth, the heat-resistant film containing polyimide as the main component, or the heat-resistant film containing liquid crystal polymer as the main component.

In the substrate for printed wiring board of the present disclosure, when the average thickness of the base layer is defined as A and the average distance between a matrix-facing surface of the copper foil and the surface of the reinforcing material layer closest to the surface facing the copper foil is defined as B, the ratio B/A is 0.003 to 0.37.

In FIG. 1, when an average thickness of base layer 51 is A and an average distance between a surface 71 of copper foil 41 facing the matrix and a surface 61 of the reinforcing material layer closest to surface 71 facing the copper foil is B, the ratio B/A is 0.003 to 0.37. This average distance B is approximately equal to the average thicknesses of matrix 2a arranged between copper foil 41 and reinforcing material layer 31.

In addition, when the average thicknesses of base layer 51 is A and the average distance between a surface 72 of copper foil 42 facing the matrix and a surface 62 of the reinforcing material layer closest to surface 72 facing the copper foil is B, the ratio B/A is 0.003 to 0.37. This average distance B is approximately equal to the average thicknesses of matrix 2c arranged between copper foil 42 and reinforcing material layer 32.

The lower limit of the ratio B/A is 0.003, and may be 0.10. The upper limit of the ratio B/A is 0.37, and may be 0.25. When the ratio B/A is less than 0.003, the transmission characteristics may be adversely affected. When the ratio B/A is 0.10 or more, the transmission characteristics are further improved. When the ratio B/A exceeds 0.37, there is a possibility that the bending characteristics are adversely affected. When the ratio B/A is 0.25 or less, the bending characteristics are further improved.

The lower limit of the ratio of the sum of the average thicknesses of the respective reinforcing material layers to the average thickness of the base layer may be 0.01, 0.20, 0.22, or 0.25. The upper limit of the ratio may be 0.99, 0.5, 0.47, or 0.45. When this ratio is less than 0.01, there is a possibility that the bending strength of the substrate for printed wiring board cannot be sufficiently improved, and there is a possibility that the occurrence of warpage due to residual stress of copper foil cannot be effectively suppressed. When the ratio is 0.20 or more, the bending strength of the substrate for printed wiring board can be further improved, and the occurrence of warpage due to residual stress of the copper foil can be more effectively suppressed. When the ratio is 0.22 or more, the bending strength of the substrate for printed wiring board can be further improved, and the occurrence of warpage due to residual stress of the copper foil can be more effectively suppressed. When the ratio is 0.25 or more, the bending strength of the substrate for printed wiring board can be particularly improved, and the occurrence of warpage due to residual stress of the copper foil can be particularly effectively suppressed. When the ratio is more than 0.99, there is a possibility that the transmission characteristics may be reduced or the bendability of the reinforcing material layer may be reduced. When this ratio is 0.5 or less, the transmission characteristics and the bendability of the reinforcing material layer are further improved. When this ratio is 0.47 or less, the transmission characteristics and the bendability of the reinforcing material layer are further improved. When this ratio is 0.45 or less, the transmission characteristics and the bendability of the reinforcing material layer are particularly improved.

The upper limit of the densities of the glass fibers forming the glass cloth may be 5 g/m³ or 3 g/m³. The lower limit of the density may be 1 g/m³ or 2 g/m³. By setting the densities of the glass fibers to 1 g/m³ to 5 g/m³, it is possible to improve the strength and the dimensional stabilities of the base layer in a well-balanced manner, and to suppress warpage during manufacturing. By setting the densities of the glass fibers to 2 g/m³ to 3 g/m³, it is possible to further improve the strength and the dimensional stabilities of the base layer in a well-balanced manner, and to further suppress the warpage during manufacturing. The term “glass fiber density” means a value measured in accordance with JIS-L1013:2010 “Testing methods for chemical fiber filament yarns”. “Tensile strength of glass fiber” and “maximum elongation of glass fiber” described later are also defined in the same manner.

The upper limit of the tensile strength of the glass fiber forming the glass cloth may be 10 GPa or 5 GPa. The lower limit of the tensile strength may be 1 GPa or 2 GPa. By setting the tensile strength of the glass fiber to 1 GPa to 10 GPa, it is possible to improve the strength and dimensional stabilities of the base layer in a well-balanced manner, and to suppress the warpage during manufacturing. By setting the tensile strength of the glass fiber to 2 GPa to 5 GPa, it is possible to further improve the strength and the dimensional stabilities of the base layer in a well-balanced manner, and to further suppress the warpage during manufacturing.

The upper limit of the tensile modulus of the glass fiber forming the glass cloth may be 200 GPa or 100 GPa. The lower limit of the tensile modulus may be 10 GPa or 50 GPa. By setting the tensile modulus of elasticity of the glass fiber to 10 GPa to 200 GPa, it is possible to improve the strength and dimensional stabilities of the base layer in a well-balanced manner, and to suppress the warpage during manufacturing. By setting the tensile modulus of elasticity of the glass fiber to 50 GPa to 100 GPa, it is possible to further improve the strength and the dimensional stabilities of the base layer in a well-balanced manner, and to further suppress the warpage during manufacturing. “Tensile elastic modulus” is a complex elastic modulus representing the relationship between tensile stress and strain, and means a value measured by a tensile tester.

The upper limit of the maximum elongation rate of the glass fiber forming the glass cloth may be 20% or 10%. The lower limit of the maximum elongation rate of the glass fiber may be 1% or 3%. By setting the maximum elongation rate of the glass fiber to 1% to 20%, it is possible to improve the strength and dimensional stability of the base layer in a well-balanced manner, and to suppress warpage during manufacturing. By setting the maximum elongation rate of the glass fiber to 3% to 10%, it is possible to improve the strength and dimensional stabilities of the base layer in a well-balanced manner, and to suppress the warpage during manufacturing.

The upper limit of the softening point of the glass fiber forming the glass cloth may be 1200° C. or 1000° C. The lower limit of the softening point of the glass fiber may be 700° C. or 800° C. When the softening point of the glass fiber exceeds 1200° C., there is a possibility that the range of material selection is narrowed. When the softening point of the glass fiber is 1000° C. or less, the range of material selection is further widened. When the softening point of the glass fiber is less than 700° C., there is a possibility that the glass fiber is softened at the time of producing the base layer to cause warpage or the like. When the softening point of the glass fiber is 800° C. or higher, the possibility that the glass fiber is softened to cause warpage or the like during the production of the base layer is further reduced. The “softening point” means a softening point measured by the ring and ball method specified in JIS-K7234:1986.

The upper limit of the relative dielectric constant of the reinforcing material may be 10, 6, or 5. The lower limit of the relative dielectric constant may be 1.2, 1.5, or 1.8. When the relative dielectric constant of the reinforcing material exceeds 10, there is a possibility that the dielectric loss becomes large and the transmission loss cannot be sufficiently reduced, and there is a possibility that a sufficient transmission rate cannot be obtained. When the relative dielectric constant of the reinforcing material is 6 or less, the transmission loss can be further reduced and the transmission rate can be further increased. When the relative dielectric constant of the reinforcing material is 5 or less, the transmission loss can be further reduced, and the transmission rate can be further increased. When the relative dielectric constant is less than 1.2, the cost may be high. When the relative dielectric constant of the reinforcing material is 1.5 or more, the cost can be further reduced, and when it is 1.8 or more, the cost can be further reduced.

The upper limit of the linear expansion coefficient of the reinforcing material may be 5×10⁻⁵/° C. or 4.7×10⁻⁵/° C. The lower limit of the linear expansion coefficient of the reinforcing material may be −1×10⁻⁴/° C. or 0/° C. When the linear expansion coefficient of the reinforcing material exceeds 5×10⁻⁵/° C., there is a possibility that occurrence of warpage due to a temperature change cannot be effectively suppressed. When the linear expansion coefficient of the reinforcing material is 4.7×10⁻⁵/° C. or less, the occurrence of warpage due to temperature change can be more effectively suppressed. When the linear expansion coefficient of the reinforcing material is less than −1×10⁻⁴/° C., the cost may be high. When the linear expansion coefficient of the reinforcing material is 0/° C. or more, the cost can be further reduced.

The upper limit of the ratio of the linear expansion coefficient of the reinforcing material to the linear expansion coefficient of the matrix may be 0.95 or 0.1. The lower limit of this ratio may be 0.001 or may be 0.002. When this ratio exceeds 0.95, there is a possibility that the occurrence of warpage of the substrate for printed wiring board cannot be effectively suppressed. When this ratio is 0.1 or less, the occurrence of warpage of the substrate for printed wiring board can be more effectively suppressed. When this ratio is less than 0.001, the cost of the reinforcing material may be high. When this ratio is 0.002 or more, the cost of the reinforcing material can be further reduced.

(Copper Foil)

Copper foil is used as the conductive layer of the substrate for printed wiring board. In FIG. 1, in the substrate for printed wiring board, copper foils 41 and 42 are directly or indirectly stacked on both surfaces of base layer 51. Copper foils 41 and 42 are stacked, for example, with an adhesive layer (the adhesive layer is not illustrated). Copper foil has excellent conductivity and flexibility, and is advantageous in terms of cost. The copper foil may be an electrolytic copper foil or a rolled copper foil. By using electrolytic copper foil or rolled copper foil, it is possible to obtain better flexibility while obtaining excellent transmission characteristics. The surface of the electrolytic copper foil is formed by electrodeposition particles of copper, and the surface of the rolled copper foil is formed by contact with a reduction roll. The rolled copper foil has a smaller surface roughness than the electrolytic copper foil, and has higher strength and bending resistance than the electrolytic copper foil.

The upper limit of the ten point average roughness (Rz) of the copper foil may be 4 μm, 1 μm, or 0.6 μm. When the ten point average roughness (Rz) of the copper foil exceeds 4 μm, unevenness of a portion on which a high-frequency signal is concentrated increases due to the skin effect, a linear flow of a current is inhibited, and an unintended transmission loss may occur. When the ten point average roughness (Rz) of the copper foil is 1 μm or less, it is possible to further reduce the unevenness of a portion where a high-frequency signal is concentrated due to the skin effect, and a current is more likely to flow linearly, and an unintended transmission loss is more unlikely to occur. When the ten point average roughness (Rz) of the copper foil is 0.6 μm or less, it is possible to further reduce the unevenness of a portion where a high-frequency signal is concentrated due to the skin effect, and a current is further likely to flow linearly, and an unintended transmission loss is further unlikely to to occur. The lower limit of the ten point average roughness (Rz) of the copper foil is not particularly limited, but may be 0.01 μm or 0.1 μm. The ten point average roughness (Rz) is a value defined in JIS-B-0601 (1994).

The upper limit of the average thicknesses of the copper foil may be 300 μm, 200 μm, or 150 μm. The lower limit of the average thicknesses of the copper foil may be 1 μm, 5 μm, or 10 μm. When the average thicknesses of the copper foil exceeds 300 μm, it may be difficult to apply the substrate for printed wiring board of the present disclosure to an electronic device requiring flexibility. When the average thicknesses of the copper foil is 200 μm or less, the substrate for printed wiring board of the present disclosure can be more easily applied to electronic devices. When the average thicknesses of the copper foil is 150 μm or less, the substrate for printed wiring board of the present disclosure can be more easily applied to electronic devices. When the average thicknesses of the copper foil is less than 1 μm, the resistance of the copper foil may increase. When the average thicknesses of the copper foil is 5 μm or more, the resistance of the copper foil becomes smaller. When the average thicknesses of the copper foil is 10 μm or more, the resistance of the copper foil is further reduced.

The upper limit of the average thicknesses of the substrate for printed wiring board may be 2.7 mm, 2.5 mm, or 2.2 mm. The lower limit of the average thicknesses of the substrate for printed wiring board may be 1 μm, 1.5 μm, or 2 μm. When the average thicknesses of the substrate for printed wiring board is greater than 2.7 mm, sufficient flexibility may not be obtained. When the average thicknesses of the substrate for printed wiring board is 2.5 mm or less, the flexibility is further improved. When the average thicknesses of the substrate for printed wiring board is 2.2 mm or less, the flexibility is further improved. When the average thicknesses of the substrate for printed wiring board is less than 1 μm, handling may be difficult. When the average thicknesses of the substrate for printed wiring board is 1.5 μm or more, handling becomes easier. When the average thicknesses of the substrate for printed wiring board is 2 μm or more, handling becomes much easier.

[Method of Manufacturing Substrate for Printed Wiring Board]

The method of manufacturing the substrate for printed wiring board may include, for example, (1) forming the base layer and (2) stacking copper foil.

(1) Forming the base layer;

First, a first formation method and a second formation method will be described as examples of a method of forming the base layer. According to the first formation method or the second formation method, the base layer can be easily and reliably formed.

The first forming method of the base layer includes a superimposing step of superimposing a resin film containing the fluororesin as the main component on both surfaces of the reinforcing material layer, and a thermocompression bonding step of thermocompression bonding the superimposed body while performing vacuum suction.

[Superimposition Step]

In this step, a resin film containing the fluororesin as the main component is superimposed on both surfaces of the reinforcing material layer. The main component of the resin film is fluororesin which is the main component of a matrix of base layer.

The volume ratio of the reinforcing material layer in the superimposed body obtained in the superimposing step may be 60 vol %, 40 vol %, or 30 vol %. The lower limit of the volume ratio of the reinforcing material layer may be 10 vol %, 20 vol %, or 25 vol %. By setting the volume ratio of the reinforcing material layer to 10 vol % to 60 vol %, the adhesiveness of the base layer, a reduction in the temperature dependence of the electrical characteristics after adhesion, and an improvement in the transmission characteristics can be achieved in a well-balanced manner. By setting the volume ratio of the reinforcing material layer to 20 vol % to 40 vol %, the adhesiveness of the base layer, a reduction in the temperature dependence of the electrical characteristics after adhesion, and an improvement in the transmission characteristics can be achieved in a more balanced manner. By setting the volume ratio of the reinforcing material layer to 25 vol % to 35 vol %, the adhesiveness of the base layer, a reduction in the temperature dependence of the electrical characteristics after adhesion, and an improvement in the transmission characteristics can be achieved in a more balanced manner.

[Thermocompression Bonding Step]

In this step, the superposed body obtained in the superposing step is subjected to thermocompression bonding while being subjected to vacuum suction. The upper limit of the thermocompression bonding temperature may be 400° C. or 300° C. The lower limit of the thermocompression bonding temperature may be the melting point of the fluororesin which is the main component of the resin film, or may be the decomposition start temperature of the fluororesin. Further, the lower limit of the thermocompression bonding temperature may be a temperature higher than the melting point of the fluororesin by 10° C. or a temperature higher than the melting point of the fluororesin by 30° C. The lower limit of the thermocompression bonding temperature may be 200° C. or 220° C. When the thermocompression bonding temperature exceeds 400° C., the resulting base layer may be deformed. When the thermocompression bonding temperature is 300° C. or lower, the base layer is less likely to be deformed. When the thermocompression bonding temperature is lower than the melting point of the fluororesin, it may be difficult to obtain the base layer in which the reinforcing material layer and the resin film are integrated. When the thermocompression bonding temperature is equal to or higher than the decomposition start temperature of the fluororesin, the base layer in which the reinforcing material layer and the resin film are integrated is more easily obtained. When the thermocompression bonding temperature is 10° C. or more higher than the melting point of the fluororesin, the base layer in which the reinforcing material layer and the resin film are integrated is more easily obtained. The “decomposition start temperature” refers to a temperature at which the fluororesin starts to thermally decompose, and the “decomposition temperature” refers to a temperature at which the mass of the fluororesin decreases by 10% due to thermal decomposition.

The pressure of the thermocompression bonding may be performed at 0.01 MPa to 1200 MPa. When the pressure of the thermocompression bonding is 0.01 MPa to 1000 MPa, the intimate contact to the base layer is improved. The pressurization time of the thermocompression bonding may be 5 seconds to 10 hours. When the pressurization time of the thermocompression bonding is 5 seconds to 10 hours, the intimate contact between the base layer and the resin film is improved.

The upper limit of the vacuum degree at the time of vacuum suction may be 10 MPa, 1 MPa, or 10 kPa. The lower limit of the vacuum degree is not particularly limited and is, for example, 0.01 Pa. By setting the vacuum degree to 10 MPa or less, the intimate contact between the resin film and the reinforcing material layer is improved. When the vacuum degree is 1 MPa or less, the intimate contact between the resin film and the reinforcing material layer is further improved. When the vacuum degree is 10 kPa or less, the intimate contact between the resin film and the reinforcing material layer is further improved. In addition, when a woven fabric or the nonwoven fabric is used as the reinforcing material layer, voids of the woven fabric or the nonwoven fabric can be reliably impregnated with the resin of the resin film, and thus the base layer in which the reinforcing material layer and the matrix are more firmly integrated can be obtained.

In the first forming method of the base layer, in order to further improve the intimate contact between the resin film and the reinforcing material layer, vacuum suction may be started before the start of thermocompression bonding.

(Second Formation Method of Base Layer)

The second forming method of the base layer includes an impregnation step of impregnating the surface and the inside of the reinforcing material layer with a composition containing the fluororesin as the main component, and a heating step of heating the impregnated composition. In the second method of forming the base layer, the reinforcing material layer is a woven fabric or the nonwoven fabric.

[Impregnation Step]

In the impregnation step, the surface and the inside of the reinforcing material layer are impregnated with a composition containing the fluororesin as the main component. Examples of the composition include the fluororesin dispersion in which fluororesin particles are dispersed in a solvent. Examples of the method of impregnating the surface and the inside of the reinforcing material layer with the composition include a method of applying the composition to the surface of the reinforcing material layer and a method of immersing the glass cloth or the resin cloth in the composition.

The volume ratio of the reinforcing material to the sum of the solid content and the reinforcing material contained in the composition may be 60 vol %, 40 vol %, or 30 vol %. The lower limit of the volume ratio of the reinforcing material may be 10 vol %, 20 vol %, or 25 vol %. By setting the volume ratio of the reinforcing material to 10 vol % to 60 vol %, it is possible to achieve adhesiveness of the base layer, a reduction in temperature dependence of electrical characteristics after adhesion, and an improvement in transmission characteristics in a well-balanced manner. When the volume ratio of the reinforcing material is 20 vol % to 40 vol %, it is possible to achieve adhesiveness of the base layer, a reduction in temperature dependence of electrical characteristics after adhesion, and an improvement in transmission characteristics in a well-balanced manner. When the volume ratio of the reinforcing material is 25 vol % to 30 vol %, it is possible to achieve adhesiveness of the base layer, a reduction in temperature dependence of electrical characteristics after adhesion, and an improvement in transmission characteristics in a more balanced manner. “Solid content” refers to a component other than the solvent in the composition.

[Heating Step]

In the heating step, the impregnated composition is heated. The heating step corresponds to a baking step in which the impregnated composition is dried and cured. After the heating step, a layer of the fluororesin is formed on the surface of the reinforcing material layer, and the inside of the reinforcing material layer is impregnated with the fluororesin.

The upper limit of the temperature in the heating step may be 400° C. or 300° C. The lower limit of the temperature in the heating step may be 150° C. or 200° C. When the temperature of the heating step is less than 150° C., the drying and curing of the impregnated composition may be insufficient. When the temperature of the heating step is 200° C. or higher, drying and curing of the composition are further promoted. When the temperature of the heating step exceeds 400° C., the resulting base layer may be deformed. When the temperature of the heating step is 300° C. or lower, the base layer is less likely to be deformed.

In the second forming method, after forming the layer of the fluororesin on the first surface of the reinforcing material layer, the layer of the fluororesin may be formed again on the second surface. In the second forming method, the fluororesin layer may be simultaneously formed on both surfaces of the reinforcing material layer.

In the second forming method, the impregnation step and the heating step may be repeated two or more times. For example, by repeatedly applying and heating the composition, a layer of the fluororesin having a predetermined thickness can be easily formed.

In the second forming method, the surface and the inside of the reinforcing material layer are impregnated with a composition containing the fluororesin as the main component. Therefore, in the second forming method, it is possible to easily and reliably obtain the base layer in which the reinforcing material layer and the matrix are more firmly integrated.

(2) Stacking Copper Foil;

First, a primer material is attached to the copper foil. When the primer material is a silane coupling agent, the primer material including the silane coupling agent, alcohol, and water is attached to the copper foil. Next, the copper foil is dried and heated as necessary to remove the alcohol in the primer material. Thereafter, the base layer is superposed on the surface of the primer material, and the obtained laminate is thermocompression-bonded by a press machine. The thermocompression bonding may be performed under reduced pressure in order to prevent bubbles or voids from being formed between the copper foil and the base layer. Further, in order to suppress oxidation of the copper foil, the thermocompression bonding may be performed under a low-oxygen condition (for example, in a nitrogen atmosphere). Thus, the substrate for printed wiring board having the adhesive layer between the copper foil and the base layer is obtained.

The upper limit of the temperature of the thermocompression bonding may be 600° C. or 500° C. The lower limit of the temperature of the thermocompression bonding may be the melting point of the fluororesin which is the main component of the matrix of base layer, or may be the decomposition start temperature of the fluororesin. The temperature may be higher than the melting point of the fluororesin by 30° C., or higher than the melting point of the fluororesin by 50° C. When the temperature of the thermocompression bonding exceeds 600° C., there is a possibility that unintended deformation occurs during production. When the temperature of the thermocompression bonding is 500° C. or lower, unintended deformation is less likely to occur during the production. When the temperature of the thermocompression bonding is lower than the melting point of the fluororesin, the intimate contact between the copper foil and the base layer may be insufficient. When the temperature of the thermocompression bonding is equal to or higher than the decomposition start temperature of the fluororesin, the intimate contact between the copper foil and the base layer is further improved. When the temperature of the thermocompression bonding is higher than the melting point of the fluororesin by 30° C. or more, the intimate contact between the copper foil and the base layer is further improved. When the temperature of the thermocompression bonding is higher than the melting point of the fluororesin by 50° C. or more, the intimate contact between the copper foil and the base layer is further improved.

The reason why the thermocompression bonding is performed at a temperature equal to or higher than the melting point of the fluororesin is that the fluororesin is not activated at a temperature lower than the melting point. In addition, by heating to a temperature equal to or higher than the decomposition start temperature of the fluororesin, the C atom of the fluororesin is radicalized, and thus the fluororesin can be further activated. That is, it is considered that the intimate contact between the copper foil and the base layer can be further promoted by setting the temperature of the thermocompression bonding to be equal to or higher than the melting point (or equal to or higher than the decomposition start temperature) of the fluororesin.

The thermocompression bonding may be performed at 0.01 MPa to 1000 MPa. When the thermocompression bonding is performed at 0.01 MPa to 1000 MPa, the intimate contact between the copper foil and the base layer is improved. The pressurization time of the thermocompression bonding may be 5 seconds to 10 hours. When the pressurization time of the thermocompression bonding is 5 seconds to 10 hours, the intimate contact between the copper foil and the base layer is improved.

<Multilayer Substrate>

In a multilayer substrate, a plurality of substrates for printed wiring boards are stacked. In the multilayer substrate, since a plurality of substrates for printed wiring boards are stacked, it is possible to reduce strain due to compression of the outermost matrix (fluororesin layer) of the multilayer substrate and to suppress a load on the copper foil disposed on the outermost side. Therefore, the multilayer substrate has excellent bending strength.

The plurality of the substrates for printed wiring board may be stacked on each other with a bonding sheet or the adhesive layer containing the silane coupling agent as the main component interposed therebetween. Since the plurality of the substrates for printed wiring board are stacked on each other with the bonding sheet or the adhesive layer containing the silane coupling agent as the main component interposed therebetween, good adhesiveness can be obtained between the plurality of substrates for printed wiring boards.

The bonding sheet is obtained by forming an adhesive into a film shape. The material of the adhesive is not particularly limited, but may be a material excellent in flexibility and heat resistance. Examples of the adhesive include resin-based adhesives such as epoxy resin, polyimide, polyester, phenol resin, polyurethane, acrylic resin, melamine resin, and polyamide-imide.

The silane coupling agent forms a siloxane bond with the fluororesin, which is the main component of the matrix of base layer, thereby improving adhesiveness. The silane coupling agent may be the silane coupling agent having a hydrophilic functional group in the molecule, or may be the silane coupling agent having a hydrolyzable silicon-containing functional group. Such silane coupling agent is chemically bonded to the fluororesin included in the matrix of base layer. The chemical bond between the silane coupling agent and the fluororesin may be formed only by a covalent bond or may include a covalent bond and a hydrogen bond. The “hydrophilic functional group” refers to a functional group composed of atoms having high electronegativity and having hydrophilicity. The “hydrolyzable silicon-containing functional group” refers to a group capable of forming a silanol group (Si—OH) by hydrolysis.

In the adhesive layer containing the silane coupling agent as the main component, a Si atom constituting a siloxane bond (hereinafter, this atom is also referred to as a “Si atom of the siloxane bond”) is covalently bonded to a C atom of the fluororesin through at least one atom of, for example, an N atom, a C atom, an O atom, and an S atom. To be specific, the Si atom of the siloxane bond is bonded to the C atom of the fluororesin through an atomic group such as —O—, —S—, —S—S—, —(CH₂)ₙ—, —NH—, —(CH₂)ₙ—NH—, —(CH₂)ₙ—O—(CH₂)ₘ— (n and m are integers of 1 or more).

The hydrophilic functional group may be any one of a hydroxyl group, a carboxyl group, a carbonyl group, an amino group, an amide group, a sulfide group, a sulfonyl group, a sulfo group, a sulfonyldioxy group, an epoxy group, a methacryl group, and a mercapto group, or a combination thereof. Among them, the hydrophilic functional group may be a hydrophilic functional group containing an N atom or a hydrophilic functional group containing an S atom. These hydrophilic functional groups further improve the surface intimate contact and adhesiveness.

The adhesive layer containing the silane coupling agent as the main component may contain two or more kinds of these hydrophilic functional groups. By imparting hydrophilic functional groups having different properties to the adhesive layer having the silane coupling agent as the main component, surface reactivity and the like can be varied. These hydrophilic functional groups can be bonded directly or through one or more C atoms to the Si atom which is a constituent of the siloxane bond.

The upper limit of the average thicknesses of the adhesive layer including the bonding sheet or the adhesive layer containing the silane coupling agent as the main component may be 200 nm or 50 nm. The lower limit of the average thicknesses of the adhesive layer may be 3 nm or 5 nm. When the average thicknesses of the adhesive layer exceeds 200 nm, the high-frequency characteristics may be insufficient due to the influence of the dielectric loss caused by the adhesive layer. When the average thicknesses of the adhesive layer is 50 nm or less, the high-frequency characteristics are further improved. When the average thicknesses of the adhesive layer is less than 3 nm, the surface activation effect is not sufficiently obtained, and there is a possibility that the adhesiveness and the intimate contact are not sufficiently obtained. When the average thicknesses of the adhesive layer is 5 nm or more, the adhesiveness and the intimate contact are further improved. In this way, by adjusting the average thicknesses of the adhesive layer, it is possible to exert the function of suppressing the transmission loss and the function of improving the intimate contact in a well-balanced manner. The average thicknesses of the adhesive layer can be determined, for example, by X-ray spectroscopy.

FIG. 2 is a schematic cross-sectional view showing the multilayer substrate according to an embodiment of the present disclosure. In a multilayer substrate 100 shown in FIG. 2, substrate for printed wiring board 1 and a substrate for printed wiring board 10 are stacked through a bonding sheet 8. In FIG. 2, the same elements as those of substrate for printed wiring board 1 of FIG. 1 are denoted by the same reference numerals, and the description thereof will not be repeated. Substrate for printed wiring board 10 includes base layer 52 and a copper foil 43 directly or indirectly stacked on one surface of base layer 52.

Also in substrate for printed wiring board 10, the ratio B/A is 0.003 to 0.37, where A is an average thickness of base layer 52, and B is an average distance between a surface 73 of copper foil 43 facing the matrix 2f and a surface 63 of a reinforcing material layer 34 closest to surface 73 facing copper foil 43.

The ratio D/A is 0.003 to 0.37, where A is an average thickness of base layer 52 of substrate for printed wiring board 10, and D is an average distance between a surface 74 of copper foil 42 of substrate for printed wiring board 1 facing a matrix 2d of substrate for printed wiring board 10 and a surface 64 of a reinforcing material layer 33 of substrate for printed wiring board 10 closest to copper foil 42 of substrate for printed wiring board 1 facing copper foil 42.

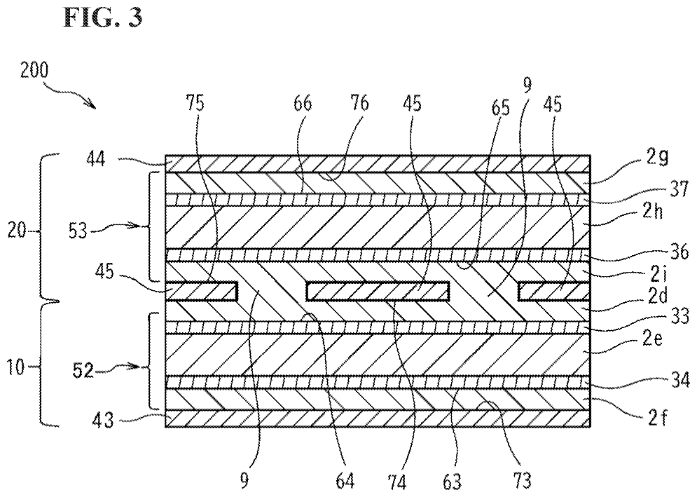

FIG. 3 is a schematic cross-sectional view showing the multilayer substrate according to another embodiment of the present disclosure. In FIG. 3, the same elements as those of substrate for printed wiring board 10 of FIG. 2 are denoted by the same reference numerals, and the description thereof will not be repeated. A substrate for printed wiring board 20 includes a base layer 53 and copper foils 44 and 45 directly or indirectly stacked on both surfaces of base layer 53. In addition, the copper foil 45 stacked on a matrix 2i of substrate for printed wiring board 20 has a plurality of through holes 9. The adhesive layer having the silane coupling agent as the main component is formed on surface 74 of copper foil 45 facing matrix 2d. That is, in a multilayer substrate 200, copper foil 45 of substrate for printed wiring board 20 and matrix 2d of substrate for printed wiring board 10 are bonded by thermocompression bonding through the adhesive layer, and substrate for printed wiring board 10 and substrate for printed wiring board 20 are stacked. As substrate for printed wiring board 10 and substrate for printed wiring board 20 are stacked by thermocompression bonding, matrix 2d of substrate for printed wiring board 10 and matrix 2i of substrate for printed wiring board 20 are filled in the through hole 9.

Also in substrate for printed wiring board 20, the ratio B/A is 0.003 to 0.37, where A is an average thickness of base layer 53, and B is an average distance between a surface 76 of copper foil 44 facing a matrix 2g and a surface 66 of the reinforcing material layer 37 closest to surface 76 facing copper foil 44.

In addition, the ratio B/A is 0.003 to 0.37, where A is an average thickness of base layer 53 of substrate for printed wiring board 20, and B is an average distance between a surface 75 of copper foil 45 facing matrix 2i and a surface 65 of a reinforcing material layer 36 closest to surface 75 of copper foil 45 facing copper foil 45.

Further, the ratio D/A is 0.003 to 0.37, where A is an average thickness of base layer 52 of substrate for printed wiring board 10, and D is an average distance between surface 74 of copper foil 45 of substrate for printed wiring board 20 facing matrix 2d of substrate for printed wiring board 10 and surface 64 of reinforcing material layer 33 of substrate for printed wiring board 10 closest to copper foil 45 of substrate for printed wiring board 20 facing copper foil 45.

[Method of Manufacturing Multilayer Substrate]

A method of manufacturing the multilayer substrate includes, for example, a step of stacking a first substrate for printed wiring board in which copper foil is directly or indirectly stacked on both surfaces of the base layer and a second substrate for printed wiring board in which copper foil is directly or indirectly stacked on only one surface of the base layer. In the first substrate for printed wiring board, the copper foil may be directly or indirectly stacked on at least a part of each of both surfaces of the base layer. In the second substrate for printed wiring board, copper foil may be directly or indirectly stacked on at least a part of one surface of the base layer.

The step of stacking the first substrate for printed wiring board and the second substrate for printed wiring board with the bonding sheet or the adhesive layer having the silane coupling agent as the main component may be, for example, the following step. First, the bonding sheet is stacked on copper foil of a first substrate for printed wiring board, or the primer material for the silane coupling agent, which is the main component of the adhesive layer, is attached thereto. Thereafter, the base layer of the second substrate for printed wiring board is stacked on the copper foil of the first substrate for printed wiring board with the bonding sheet or the adhesive layer, and thermocompression bonding is performed, whereby the first substrate for printed wiring board and the second substrate for printed wiring board can be stacked. The step of stacking the first substrate for printed wiring board and the second substrate for printed wiring board with the adhesive layer having the silane coupling agent as the main component is the same step as the step of stacking the copper foil described above.

In addition, another method of manufacturing the multilayer substrate may include a step of bonding two substrates for printed wiring boards, in which copper foil is directly or indirectly stacked on both surfaces of the base layer, with the bonding sheet.

The substrate for printed wiring board according to one aspect of the present disclosure and the multilayer substrate according to another aspect of the present disclosure have excellent bending strength. Therefore, it can be suitably used in portable devices such as portable information devices and portable communication terminals.

### Other Embodiments

The embodiments disclosed above are to be considered in all respects as illustrative and not restrictive. The scope of the present disclosure is not limited to the configurations of the above-described embodiments, but is defined by the claims, and is intended to include meanings equivalent to the claims and all modifications within the scope.

In the above embodiment, the reinforcing material layer is composed of two layers, but may be composed of one layer or three or more layers. Further, the matrix has three layers, but may have two layers or four or more layers.

In the above embodiment, the multilayer substrate has two substrates for printed wiring boards, but may have three or more substrates for printed wiring boards.

### EXAMPLES

Hereinafter, the present disclosure will be described in more detail with reference to examples, but the present disclosure is not limited to the following examples.

<Preparation of Substrate for Printed Wiring Board>

### Test Example 1

A substrate for printed wiring board of Test Example 1 was prepared by the following procedure. First, the primer material was attached to the electrolytic copper foil using a dipping method, and then dried and heated at 110° C. to form the primer material layer on the copper foil. Then, the electrolytic copper foil, the base layer having three layers of matrix (fluororesin layer) and two layers of reinforcing material layer, and the electrolytic copper foil were stacked in this order such that the primer material layer faced the base layer. The obtained laminate is thermocompression-bonded by a press machine to obtain the substrate for printed wiring board having the adhesive layer between the copper foil and the base layer. As specific configurations of the base layer, Neoflon FEP (an average thickness of 20 μm) manufactured by DAIKIN INDUSTRIES, LTD., glass cloth (IPC-standard style 1015, an average thickness of 15 μm), Neoflon FEP (an average thickness of 45 μm) manufactured by DAIKIN INDUSTRIES, LTD., glass cloth (IPC-standard style 1015, an average thickness of 15 μm), and Neoflon FEP (an average thickness of 20 μm) manufactured by DAIKIN INDUSTRIES, LTD. were used. The thermocompression bonding was performed under the conditions of a temperature of 320° C., a pressure of 6 MPa, and a pressurization time of 40 minutes. The average thickness of the base layer was 115 μm. As the primer material, a material containing 1 mass % of 3-aminopropyltrimethoxysilane and ethanol was used. Water was not added to the primer material. That is, as water, moisture present in air and moisture contained in ethanol as an impurity were used.

### Test Example 2

A substrate for printed wiring board of Test Example 2 was prepared by the same steps as in Test Example 1 except that rolled copper foil was used instead of electrolytic copper foil, Neoflon PFA (an average thickness of 20 μm) manufactured by DAIKIN INDUSTRIES, LTD. was used instead of Neoflon FEP (an average thickness of 20 μm) manufactured by DAIKIN INDUSTRIES, LTD., and Neoflon PFA (an average thickness of 45 μm) manufactured by DAIKIN INDUSTRIES, LTD. was stacked instead of Neoflon FEP (an average thickness of 45 μm) manufactured by DAIKIN INDUSTRIES, LTD.

### Test Example 3

The substrate for printed wiring board of Test Example 3 was prepared by stacking rolled copper foil, Neoflon FEP (an average thickness of 7 μm) manufactured by DAIKIN INDUSTRIES, LTD., glass cloth (IPC-standard style 1015, an average thickness of 15 μm), Neoflon PFA (an average thickness of 70 μm) manufactured by DAIKIN INDUSTRIES, LTD., glass cloth (IPC-standard style 1015, an average thickness of 15 μm), Neoflon FEP (an average thickness of 7 μm) manufactured by DAIKIN INDUSTRIES, LTD., and rolled copper foil in this order. The hot pressing was performed under the same conditions as in Test Example 1.

### Test Example 4

A rolled copper foil was coated with an aqueous coating material of PTFE adjusted to a solid content of 25%, and dried in a nitrogen furnace at 380° C. for 10 minutes to prepare the rolled copper foil having a PTFE layer with a coating thickness of about 0.3 μm. A rolled copper foil coated with PTFE, the glass cloth (IPC-standard style 1015, an average thickness of 15 μm), Neoflon FEP (an average thickness of 85 μm) manufactured by DAIKIN INDUSTRIES, LTD., the glass cloth (IPC-standard style 1015, an average thickness of 15 μm), and the rolled copper foil coated with PTFE were stacked in this order. Hot pressing was performed under the same conditions as in Test Example 1. The substrate for printed wiring board of Test Example 4 was prepared by stacking the PTFE layer on the glass cloth side.

### Test Example 5

A substrate for printed wiring board of Test Example 5 was prepared by stacking electrolytic copper foil, Neoflon FEP (an average thickness of 42.5 μm) manufactured by DAIKIN INDUSTRIES, LTD., glass cloth (IPC-standard style 1030, an average thickness of 30 μm), Neoflon FEP (an average thickness of 42.5 μm) manufactured by DAIKIN INDUSTRIES, LTD., and electrolytic copper foil in this order. The hot pressing was performed under the same conditions as in Test Example 1.

### Test Example 6

A substrate for printed wiring board of Test Example 6 was prepared by stacking electrolytic copper foil, Neoflon FEP (an average thickness of 46 μm) manufactured by DAIKIN INDUSTRIES, LTD., glass cloth (IPC-standard style 1015, an average thickness of 15 μm), Neoflon FEP (an average thickness of 46 μm) manufactured by DAIKIN INDUSTRIES, LTD., and electrolytic copper foil in this order. The hot pressing was performed under the same conditions as in Test Example 1.

### Test Example 7

A substrate for printed wiring board of Test Example 7 was prepared by stacking electrolytic copper foil, Neoflon FEP (an average thickness of 100 μm) manufactured by DAIKIN INDUSTRIES, LTD., and electrolytic copper foil in this order. The hot pressing was performed under the same conditions as in Test Example 1.

### Test Example 8

A substrate for printed wiring board of Test Example 8 was prepared by stacking rolled copper foil, Neoflon FEP (an average thickness of 25 μm) manufactured by DAIKIN INDUSTRIES, LTD., polyimide film (an average thickness of 25 μm), Neoflon FEP (an average thickness of 25 μm) manufactured by DAIKIN INDUSTRIES, LTD., polyimide film (an average thickness of 25 μm), Neoflon FEP (an average thickness of 25 μm) manufactured by DAIKIN INDUSTRIES, LTD., and rolled copper foil in this order. The hot pressing was performed under the same conditions as in Test Example 1.

### Test Example 9

A substrate for printed wiring board of Test Example 9 was prepared by stacking rolled copper foil, Neoflon FEP (an average thickness of 25 μm) manufactured by DAIKIN INDUSTRIES, LTD., a liquid crystal polymer film (an average thickness of 25 μm), Neoflon FEP (an average thickness of 25 μm) manufactured by DAIKIN INDUSTRIES, LTD., a liquid crystal polymer film (an average thickness of 25 μm), Neoflon FEP (an average thickness of 25 μm) manufactured by DAIKIN INDUSTRIES, LTD., and rolled copper foil in this order. The hot pressing was performed under the same conditions as in Test Example 1.

### Test Example 10

A substrate for printed wiring board of Test Example 10 was prepared by stacking rolled copper foil, Neoflon FEP (an average thickness of 25 μm) manufactured by DAIKIN INDUSTRIES, LTD., aramid paper (an average thickness of 50 μm) manufactured by Du Pont Teijin Advanced Paper Co., Ltd., Neoflon FEP (an average thickness of 25 μm) manufactured by DAIKIN INDUSTRIES, LTD., and rolled copper foil in this order. The hot pressing was performed under the same conditions as in Test Example 1.

<Preparation of Multilayer Substrate>

### Test Example 11

A substrate for printed wiring board of Test Example 1 and the substrate for printed wiring board in which electrolytic copper foil was not formed on one surface of the substrate for printed wiring board of Test Example 1 were prepared. These substrates for printed wiring boards were hot-pressed under the same conditions as in Test Example 1 with the bonding sheet made of an epoxy-based resin so that copper foil was disposed on both end sides, thereby producing the multilayer substrate of Test Example 11.

### Test Example 12

A substrate for printed wiring board of Test Example 6 and the substrate for printed wiring board in which electrolytic copper foil was not formed on one surface of the substrate for printed wiring board of Test Example 6 were prepared. These substrates for printed wiring boards were hot-pressed under the conditions of 180° C., 30 minutes, and 2 MPa with bonding sheets made of epoxy-based resins so that copper foil was disposed on both end sides, thereby producing the multilayer substrate of Test Example 12.

[Evaluation]

The substrates for printed wiring board of Test Example 1 to Test Example 10 and the multilayer substrates of Test Example 11 to Test Example 12 were evaluated for the following items.

(Bending Strength)

The bending strength was evaluated by the following procedure. Test pieces having a long side of 100 mm and a short side of 25 mm were prepared from the substrate for printed wiring board and the multilayer substrate of each test example. These test pieces were bent while winding the long sides around a metal cylinder having a radius of 2.5 mm until the bending angle became 90° (normal direction 90°). Next, these test pieces were returned to the state before bending, and was bent in the same procedure with the surface, having not been in contact with the cylinder, facing the cylinder side (90° in the reverse direction). Then, after bending, once by 90° in the forward direction and once by 90° in the reverse direction as one time of bending, mountain fold portions and valley fold portions of the bent portion were observed using a microscope, and the number of bending times until breakage occurred was measured. The evaluation results are shown in Table 1.

(Warpage Amount After Single-Side Etching)

The prepared substrate was cut to be a sample of 100 mm square, Elep Masking N-380 manufactured by Nitto Denko Corporation was attached to one side thereof, and the sample was immersed in a copper chloride aqueous solution. After the copper foil on the side to which the masking was not applied was completely dissolved, the copper foil was rinsed twice with ion-exchanged water, moisture was wiped off with a waste cloth, and then the masking was removed. Then, the sample was left on a surface plate with the copper foil side facing downward, and the heights of four points of the 100 mm square sample from the surface plate were measured using a rule. When no warpage was observed, the measurement was performed again with the fluororesin side facing upward. Warping to the fluororesin side was taken as a positive value, and warping to the copper foil side was taken as a negative value. The diameter (<p) of the cylinder was measured when the warpage was strong and the cylinder was formed.

TABLE 1

| | | | Test Example | | | | | |
|---|---|---|---|---|---|---|---|---|
| | | | 1 | 2 | 3 | 4 | 5 | 6 |
| Form | | | Substrate for | Substrate for | Substrate for | Substrate for | Substrate for | Substrate for |
| | | | printed | printed | printed | printed | printed | printed |
| | | | wiring board | wiring board | wiring board | wiring board | wiring board | wiring board |
| Base | Matrix | Fluororesin layer 1 | FEP | PFA | FEP | PTFE | FEP | FEP |
| layer | | | 20 μm | 20 μm | 7 μm | 0.3 μm | 42.5 μm | 46 μm |
| | | Fluororesin layer 2 | FEP | PFA | PFA | FEP | — | — |
| | | | 45 μm | 45 μm | 70 μm | 85 μm | | |
| | | Fluororesin layer 3 | FEP | PFA | FEP | PTFE | FEP | FEP |
| | | | 20 μm | 20 μm | 7 μm | 0.3 μm | 42.5 μm | 46 μm |
| | Reinforcing material layer | | 2 layers of | 2 layers of | 2 layers of | 2 layers of | 1 layer of | 1 layer of |
| | | | glass cloth | glass cloth | glass cloth | glass cloth | glass cloth | glass cloth |
| | | | 15 μm | 15 μm | 15 μm | 15 μm | 30 μm | 15 μm |
| | Total average thicknesses of | | 30 | 30 | 30 | 30 | 30 | 15 |
| | reinforcing material layer [μm] | | | | | | | |
| | Ratio of average thicknesses of | | 0.26 | 0.26 | 0.26 | 0.26 | 0.26 | 0.14 |
| | reinforcing material layer to the | | | | | | | |
| | average thickness A of base layer | | | | | | | |
| | Average distance B or D | | 20 | 20 | 7 | 0.3 | 43 | 46 |
| | between surface of copper foil | | | | | | | |
| | and surface of reinforcing | | | | | | | |
| | material layer [μm] | | | | | | | |
| | Ratio B/A or ratio D/A | | 0.17 | 0.17 | 0.06 | 0.003 | 0.37 | 0.43 |
| | Average thicknesses of base | | 115 | 115 | 114 | 116 | 115 | 107 |
| | layer A [μm] | | | | | | | |
| Copper | Type of copper foil | | Electrolysis | Rolling | Rolling | Rolling | Electrolysis | Electrolysis |
| foil | Thickness of copper foil [μm] | | 12.0 | 12.0 | 12.0 | 12.0 | 12.0 | 12.0 |
| | Number of copper foil | | 2 | 2 | 2 | 2 | 2 | 2 |
| Bonding | Material | | — | — | — | — | — | — |
| sheet | Average thicknesses [μm] | | — | — | — | — | — | — |
| Number of base layer | | | 1 | 1 | 1 | 1 | 1 | 1 |
| Total average thicknesses [μm] | | | 139 | 139 | 138 | 140 | 139 | 131 |
| Warpage amount after single-side etching [mm] | | | 3 | −2 | −2 | 1 | 2 | 25 |
| Bending strength | | | 130 | 250 | 250 | 300 | 65 | 55 |
| Number of times until breakage occurred | | | | | | | | |
| | | | Test Example | | | | | |
| | | | 7 | 8 | 9 | 10 | 11 | 12 |
| Form | | | Substrate for | Substrate for | Substrate for | Substrate for | Multilayer | Multilayer |
| | | | printed | printed | printed | printed | substrate | substrate |
| | | | wiring board | wiring board | wiring board | wiring board | | |
| Base | Matrix | Fluororesin layer 1 | FEP | FEP | FEP | FEP | FEP | FEP |
| layer | | | 100 μm | 25 μm | 25 μm | 25 μm | 20 μm | 46 μm |
| | | Fluororesin layer 2 | — | FEP | FEP | — | FEP | — |
| | | | | 25 μm | 25 μm | | 45 μm | |
| | | Fluororesin layer 3 | — | FEP | FEP | FEP | FEP | FEP |
| | | | | 25 μm | 25 μm | 25 μm | 20 μm | 46 μm |

| | | | | | | | |
|---|---|---|---|---|---|---|---|
| | Reinforcing material layer | — | 2 layers of | 2 layers of | 1 layer of | 2 layers of | 1 layer of |
| | | | polyimide | liquid crystal | aramid paper | glass cloth | gloss cloth |
| | | | film | polymer film | 50 μm | 15 μm | 15 μm |
| | | | 25 μm | 25 μm | | | |
| | Total average thicknesses of | — | 50 | 50 | 50 | 30 | 15 |
| | reinforcing material layer [μm] | | | | | | |
| | Ratio of average thicknesses of | — | 0.40 | 0.40 | 0.50 | 0.26 | 0.14 |
| | reinforcing material layer to the | | | | | | |
| | average thickness A of base layer | | | | | | |
| | Average distance B or D | — | 25 | 25 | 25 | 20 | 46 |
| | between surface of copper foil | | | | | | |
| | and surface of reinforcing | | | | | | |
| | material layer [μm] | | | | | | |
| | Ratio B/A or ratio D/A | — | 0.20 | 0.20 | 0.25 | 0.17 | 0.43 |
| | Average thicknesses of base | 100 | 125 | 125 | 100 | 115 | 107 |
| | layer A [μm] | | | | | | |
| Copper | Type of copper foil | Electrolysis | Rolling | Rolling | Rolling | Electrolysis | Electrolysis |
| foil | Thickness of copper foil [μm] | 12.0 | 12.0 | 12.0 | 12.0 | 12.0 | 12.0 |
| | Number of copper foil | 2 | 2 | 2 | 2 | 3 | 3 |
| Bonding | Material | — | — | — | — | Epoxy resin | Epoxy resin |
| sheet | Average thicknesses [μm] | — | — | — | — | 25 | 25 |

| | | | | | | |
|---|---|---|---|---|---|---|
| Number of base layer | 1 | 1 | 1 | 1 | 2 | 2 |
| Total average thicknesses [μm] | 124 | 149 | 149 | 124 | 291 | 275 |
| Warpage amount after single-side etching [mm] | Cylinder | 15 | — | — | — | — |
| | φ30 | | | | | |
| Bending strength | 50 | 300 | 290 | 280 | 30 | 15 |
| Number of times until breakage occurred | | | | | | |

In Table 1, a portion corresponding to matrix 2a, 2d or 2g is denoted as the fluororesin layer 1, a portion corresponding to matrix 2b, 2e or 2h is denoted as the fluororesin layer 2, and a portion corresponding to matrix 2c, 2f or 2i is denoted as the fluororesin layer 3.

As shown in Table 1, in the substrates for printed wiring boards of Test Examples 1 to 5 and Test Examples 8 to 10 in which the ratio B/A was 0.003 to 0.37, and the multilayer substrate of Test Example 11 in which the ratio B/A and the ratio D/A were 0.003 to 0.37, the bending strength and the warpage amount after single-side etching were favorable. The substrate for printed wiring boards of Test Example 6 in which the ratio B/A and the ratio D/A were out of the range of 0.003 to 0.37 and Test Example 7 in which the reinforcing material layer was not included were inferior in the bending strength and the warpage amount after one side etching. Further, the multilayer substrate of Test Example 12 in which the ratio B/A and the ratio D/A were out of the range of 0.003 to 0.37 was inferior in bending strength.

From the above results, it was shown that the substrate for printed wiring board according to one aspect of the present disclosure and the multilayer substrate according to another aspect of the present disclosure are excellent in bending strength and an effect of suppressing warpage after etching.

### DESCRIPTION OF SYMBOLS

1, 10, 20 substrate for printed wiring board
2a, 2b, 2c, 2d, 2e, 2f, 2g, 2h, 2i matrix of base layer
31, 32, 33, 34, 35, 36 reinforcing material layer
41, 42, 43, 44, 45 copper foil
51, 52, 53 base layer
61, 62, 63, 64, 65, 66 copper foil-facing surface of reinforcing material layer closest to matrix-facing surface of copper foil
71, 72, 73, 74, 75, 76 matrix-facing surface of copper foil
8 bonding sheet
9 through hole
100, 200 multilayer substrate
A average thickness of base layer
b distance between matrix-facing surface of copper foil and copper foil-facing surface of reinforcing material layer closest to matrix-facing surface of copper foil
d distance between surface of copper foil on which second substrate for printed wiring board is stacked and copper foil-facing surface of reinforcing material layer of second substrate for printed wiring board closest to copper foil

1. A substrate for a printed wiring board, comprising:
a base layer; and
a copper foil directly or indirectly stacked on at least a part of one or both surfaces of the base layer,
wherein the base layer includes a matrix containing a fluororesin as a main component and one or more reinforcing material layers included in the matrix, and
a ratio B/A is 0.003 to 0.37, where A is an average thickness of the base layer, and B is an average distance between a surface of the copper foil facing the matrix and a surface of a reinforcing material layer closest to the surface of the copper foil facing the copper foil.

2. The substrate for a printed wiring board according to claim 1, wherein
the ratio B/A is 0.10 to 0.25.

3. The substrate for a printed wiring board according to claim 1, wherein
the fluororesin is any one of a tetrafluoroethylene-hexafluoropropylene copolymer, a tetrafluoroethylene-perfluoroalkyl vinyl ether copolymer, and polytetrafluoroethylene or a combination thereof.

4. The substrate for a printed wiring board according to claim 1, wherein
a ratio of a sum of average thicknesses of the one or more reinforcing material layers to the average thickness of the base layer is 0.01 to 0.99.

5. The substrate for a printed wiring board according to claim 1, wherein
a ratio of a sum of average thicknesses of the one or more reinforcing material layers to the average thickness of the base layer is 0.20 to 0.50.

6. The substrate for a printed wiring board according to claim 1, wherein
a ratio of a sum of average thicknesses of the one or more reinforcing material layers to the average thickness of the base layer is 0.22 to 0.47.

7. The substrate for a printed wiring board according to claim 1, wherein
a ratio of a sum of average thicknesses of the one or more reinforcing material layers to the average thickness of the base layer is 0.25 to 0.45.

8. The substrate for a printed wiring board according to claim 1, wherein
the one or more reinforcing material layers each include a glass cloth, a heat-resistant film, a resin cloth, or a nonwoven fabric.

9. The substrate for a printed wiring board according to claim 1, wherein
the copper foil is electrolytic copper foil or rolled copper foil.

10. The substrate for a printed wiring board according to claim 1, wherein
the matrix is divided into a plurality of layers.

11. A multilayer substrate comprising:
a plurality of the substrates for a printed wiring board according to claim 1 stacked on each other.

12. The multilayer substrate according to claim 11, wherein
the plurality of the substrates for a printed wiring board are stacked on each other with a bonding sheet or an adhesive layer containing a silane coupling agent as a main component interposed therebetween.

13. The multilayer substrate according to claim 11, comprising:
a first substrate for a printed wiring board and a second substrate for a printed wiring board stacked on each other,
wherein the first substrate for a printed wiring board and the second substrate for a printed wiring board are each the substrate for a printed wiring board according to the substrate for the printed wiring board, comprising:
the base layer; and
the copper foil directly or indirectly stacked on at least the part of one or both surfaces of the base layer,
wherein the base layer includes the matrix containing the fluororesin as the main component and one or more reinforcing material layers included in the matrix, and
the ratio B/A is 0.003 to 0.37, where A is the average thickness of the base layer, and B is the average distance between the surface of the copper foil facing the matrix and the surface of the reinforcing material layer closest to the surface of the copper foil facing the copper foil,
in the first substrate for a printed wiring board, the copper foil is directly or indirectly stacked on at least a part of each of both surfaces of the base layer, and in the second substrate for a printed wiring board, the copper foil is directly or indirectly stacked on at least a part of one surface of the base layer,
among the copper foils of the first substrate for a printed wiring board, the copper foil on which the second substrate for a printed wiring board is stacked is a first copper foil,
the reinforcing material layer of the second substrate for a printed wiring board closest to the first copper foil is a first reinforcing material layer, and
a ratio D/A is 0.003 to 0.37, where A is an average thickness of the base layer of the second substrate for a printed wiring board, and D is an average distance between a surface of the first copper foil facing the matrix of the second substrate for a printed wiring board and a surface of the first reinforcing material layer facing the first copper foil.
